(19) United States
(12) Patent Application Publication
(10) Pub. No.: US 2013/0075585 A1
(43) Pub. Date: Mar. 28, 2013

(54) SOLID IMAGING DEVICE

(71) Applicants: Mitsuyoshi Kobayashi, Kanagawa-ken (JP); Hideyuki Funaki, Tokyo (JP); Risako Ueno, Tokyo (JP); Kazuhiro Suzuki, Tokyo (JP)

(72) Inventors: Mitsuyoshi Kobayashi, Kanagawa-ken (JP); Hideyuki Funaki, Tokyo (JP); Risako Ueno, Tokyo (JP); Kazuhiro Suzuki, Tokyo (JP)

(73) Assignee: KABUSHIKI KAISHA TOSHIBA, Tokyo (JP)

(21) Appl. No.: 13/361,293

(22) Filed: Jan. 30, 2012

(30) Foreign Application Priority Data
Sep. 27, 2011 (JP) 2011-210936

(51) Int. Cl. H01L 27/146

(52) U.S. Cl. 250/208.1

(57) ABSTRACT

According to one embodiment, a solid imaging device includes an imaging substrate, an imaging lens, a microlens array substrate and a polarizing plate array substrate. The imaging substrate has a plurality of pixels formed on an upper side thereof. The imaging lens is provided above the imaging substrate. The optical axis in the imaging lens intersects with the upper side of the imaging substrate. The microlens array substrate is provided between the imaging substrate and the imaging lens. A surface in the microlens array substrate has a plurality of microlenses arranged two-dimensionally. The surface of the microlens array intersects with the optical axis. The polarizing plate array substrate is provided between the imaging substrate and the imaging lens. The plurality of kinds of polarizing plates in the polarizing plate array substrate having polarization axes in mutually different directions are arranged two dimensionally.

### CROSS-REFERENCE TO RELATED APPLICATIONS

This application is based upon and claims the benefit of priority from the prior Japanese Patent Application No. 2011-210936, filed on Sep. 27, 2011; the entire contents of which are incorporated herein by reference.

### FIELD

Embodiments described herein relate generally to a solid imaging device.

### BACKGROUND

For the suppression of system cost, as a distance measuring system without using reference light, there is triangulation making use of parallax. However, when carrying out triangulation, poor image quality would result in lower accuracy of measuring a distance between subjects. Moreover, since it is difficult to separate the subjects having similar colors, the accuracy of a calculable distance between the subjects is lowered.

### BRIEF DESCRIPTION OF THE DRAWINGS

FIG. 1 is a block diagram illustrating a solid imaging device according to a first embodiment;

FIG. 2 is an optical model diagram illustrating the solid imaging device according to the first embodiment;

FIG. 3A is a top view illustrating a polarizing plate array substrate in the first embodiment;

FIG. 3B is a perspective view illustrating the polarizing plate array substrate and a microlens array substrate in the first embodiment;

FIG. 4A is a diagram illustrating an image formed for each microlens in the first embodiment;

FIG. 4B is a diagram illustrating an image formed by light polarized by a polarizing plate having a single polarization axis in FIG. 4A;

FIG. 4C is a diagram illustrating a two-dimensional image obtained by processing the image of FIG. 4B;

FIG. 5 is a flowchart diagram illustrating a method of obtaining a polarization major axis from an image captured in a second embodiment;

FIG. 6A is a diagram illustrating an image formed for each microlens in the second embodiment;

FIG. 6B is a diagram illustrating a two-dimensional image obtained by image processing of the image of FIG. 6A;

FIG. 7 is a chart diagram illustrating a relationship between the polarization axis of the polarization plate and the light intensity of the subject in the second embodiment, in which the horizontal axis indicates an angle of the polarization axis, and the vertical axis indicates the light intensity;

FIG. 8A is a diagram illustrating a polarizing plate array substrate in a modified example of the second embodiment;

FIG. 8B is a diagram illustrating an image formed for each microlens;

FIG. 8C is a chart diagram illustrating a relationship between the polarization axis of the polarization plate and the light intensity of the subject, in which the horizontal axis indicates an angle of the polarization axis, and the vertical axis indicates the light intensity;

FIG. 9A is a diagram illustrating a polarizing plate array substrate in the modified example of the second embodiment;

FIG. 9B is a diagram illustrating an image formed for each microlens;

FIG. 9C is a chart diagram illustrating a relationship between the polarization axis of the polarization plate and the light intensity of the subject, in which the horizontal axis indicates an angle of the polarization axis, and the vertical axis indicates the light intensity;

FIG. 10 is a flowchart diagram illustrating a method of matching images in a third embodiment;

FIG. 11 is a diagram illustrating an image formed for each microlens in the third embodiment; and

FIG. 12 is an optical model diagram illustrating a solid imaging device 2 according to a modified example of the second and third embodiments.

### DETAILED DESCRIPTION

In general, according to one embodiment, a solid imaging device includes an imaging substrate, an imaging lens, a microlens array substrate and a polarizing plate array substrate. The imaging substrate has a plurality of pixels formed on an upper side thereof. The imaging lens is provided above the imaging substrate. The optical axis in the imaging lens intersects with the upper side of the imaging substrate. The microlens array substrate is provided between the imaging substrate and the imaging lens. A surface in the microlens array substrate has a plurality of microlenses arranged two-dimensionally. The surface of the microlens array intersects with the optical axis. The polarizing plate array substrate is provided between the imaging substrate and the imaging lens. The plurality of kinds of polarizing plates in the polarizing plate array substrate having polarization axes in mutually different directions are arranged two dimensionally. A light polarized by one of the polarizing plates is condensed by one of the microlenses to form an image on the upper side of the imaging substrate.

Various embodiments will be described hereinafter with reference to the accompanying drawings.

### First Embodiment

Embodiments of the invention will now be described with reference to the drawings.

First, a first embodiment will be described.

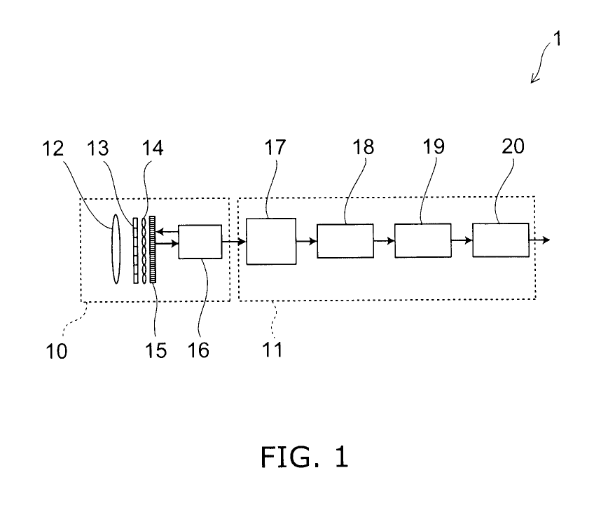

FIG. 1 is a block diagram illustrating a solid imaging device according to a first embodiment.

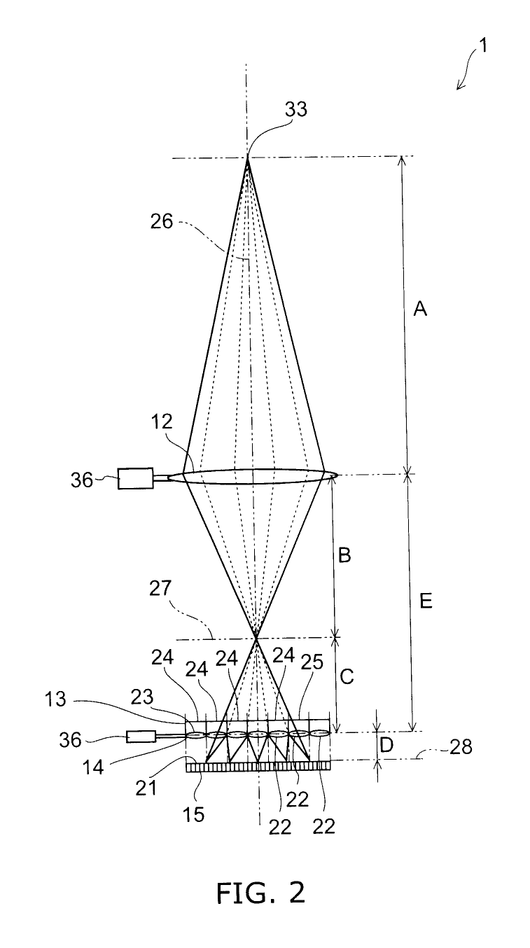

FIG. 2 is an optical model diagram illustrating the solid imaging device according to the first embodiment.

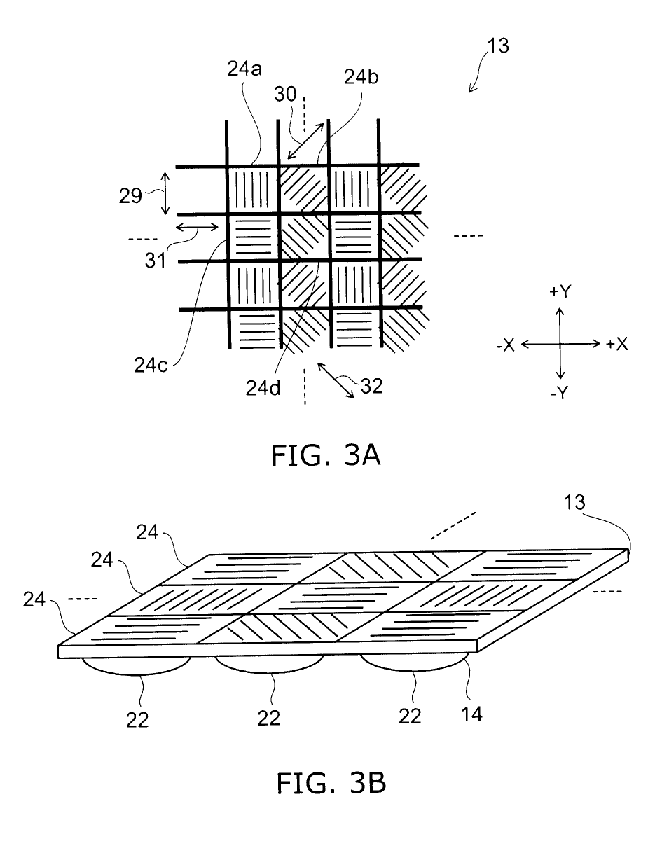

FIG. 3A is a top view illustrating a polarizing plate array substrate in the first embodiment.

FIG. 3B is a perspective view illustrating the polarizing plate array substrate and a microlens array substrate in the first embodiment.

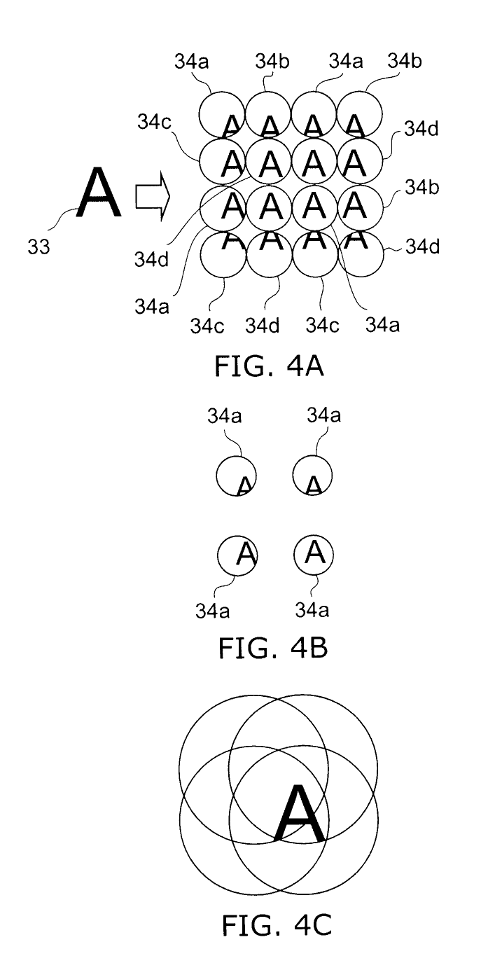

FIG. 4A is a diagram illustrating an image formed for each microlens in the first embodiment.

FIG. 4B is a diagram illustrating an image formed by light polarized by a polarizing plate having a single polarization axis in FIG. 4A.

FIG. 4C is a diagram illustrating a two-dimensional image obtained by processing the image of FIG. 4B.

As illustrated in FIG. 1, a solid imaging device 1 according to the embodiment includes an imaging module section 10 and an ISP (Image Signal Processor) 11.

The imaging module section 10 includes an imaging lens 12, a polarizing plate array substrate 13, a microlens array substrate 14, an imaging substrate 15 and an imaging circuit 16.

The imaging lens 12 is an optical element for taking light from the subject into the imaging substrate 15. The imaging substrate 15 functions as an element for converting the light taken in by the imaging lens 12 into charges. On the imaging substrate 15, a plurality of pixels are arranged in the form of a two-dimensional array. Between the imaging lens 12 and the imaging substrate 15, the polarizing plate array substrate 13 and the microlens array substrate 14 are disposed. The positional relationship between the polarizing plate array substrate 13 and the microlens array substrate 14 is not limited to the one shown in FIG. 1, and the order of disposing the polarizing plate array substrate 13 and the microlens array substrate 14 may be switched.

In the imaging circuit 16, a drive circuit section for driving each of the pixels arranged in the form of array on an upper side of the imaging substrate 15, and a pixel signal processing circuit section for processing a signal output from the pixel are provided. The drive circuit section includes a vertical section circuit for sequentially selecting pixels to be driven in the vertical direction row by row; a horizontal section circuit for sequentially selecting the pixels in the horizontal direction by column by column; and a timing generator circuit for driving these circuits by various kinds of pulses. The pixel signal processing circuit section includes an AD converter circuit for converting an analog electric signal from the pixel area into a digital signal, and a gain adjusting amplifier circuit for adjusting the gain and performing an amplifying operation.

ISP 11 includes a camera module interface 17, an image capturing section 18, a signal processing section 19 and a driver interface 20. A RAW image obtained by imaging by the imaging module section 10 is taken from the camera module interface 17 into the image capturing section 18.

The signal processing section 19 performs signal processing with respect to the RAW image taken into the image capturing section 18. The driver interface 20 outputs an image signal having been subjected to signal processing in the signa processing section 19 to the outside of the solid imaging device 1, for example, to a memory device (not shown) or a display driver (not shown). The display driver displays the image having been captured by the imaging module section 10 and having been processed by the ISP 11.

Next, an optical system of the imaging module section 10 in the solid imaging device 1 will be described.

As shown in FIG. 2, the imaging substrate 15 is provided in the solid imaging device 1. On the upper side 21 of the imaging substrate 15, a plurality of pixels are arranged in the form of the two dimensional array.

On the side of the upper surface 21 of the imaging substrate 15, the microlens array substrate 14 is provided. The microlens array substrate 14 is disposed in parallel to the imaging substrate 15. On the microlens array substrate 14, a plurality of microlenses 22 are arranged two-dimensionally within the plane parallel to the upper side 23 of the microlens array substrate 14. On the side of the upper surface 23 of the microlens array substrate 14, the polarizing plate array substrate 13 is provided.

The polarizing plate array substrate 13 is disposed in parallel with respect to the microlens array substrate 14. On the polarizing plate array substrate 13, a plurality of polarizing plates 24 are arranged two-dimensionally within the plane parallel to the upper side 25 of the polarizing plate array substrate 13. On the side of the upper surface 25 of the polarizing plate array substrate 13, the imaging lens 12 is provided. Moreover, an imaging plane 28 of each microlens 22 by the light having passed through the imaging lens 12 is set on the upper surface 21 of the imaging substrate 15.

As shown in FIG. 3A, when the polarizing plate array substrate 13 is viewed in the vertical direction to the plane, the polarizing plates 24 are arranged in a matrix form. Each of the polarizing plates 24 has a polarizing axis. Hereinafter, an orthogonal coordinate system will be adopted to explain the polarizing plate array substrate 13. In the orthogonal coordinate system, the upper direction in the diagram is defined to be +Y-direction, and the direction opposite to the +Y-direction is defined to be −Y-direction. The “+Y-direction” and “−Y-direction” may also be referred to as a general term “Y-direction”. The direction rotated by 90 degrees from the +Y-direction in the clockwise direction is defined to be +X-direction, and the direction opposite to the +X-direction is defined to be −X-direction. The “+X-direction” and “−X-direction” may be also referred to as a general term “X-direction”.

A direction 29 of the polarization axis of a single polarizing plate 24a is defined to be the Y-direction. Then, an angle of this direction 29 is set to “0 degree”. A direction 30 of the polarization axis of a polarizing plate 24b adjacent to the +X-direction of the polarizing plate 24a is defined to be a direction 45 degrees inclined in the clockwise direction from the direction 29 at 0 degree. An angle of this direction 30 is set to “45 degrees”. A direction 31 of the polarization axis of a polarizing plate 24c adjacent to the −Y-direction of the polarizing plate 24a is defined to be a direction orthogonal to the direction 29 at 0 degree. An angle of this direction 31 is set to “90 degrees”. A direction 32 of the polarization axis of a polarizing plate 24d adjacent to the +X-direction of the polarizing plate 24c is defined to be a direction orthogonal to the direction 30. An angle of this direction 32 is set to “135 degrees”. The direction of the polarization axis is referred to as “polarization axis angle”.

As shown in FIG. 3B, the respective polarization plates 24 are disposed on the corresponding microlenses 22. As a result, the polarized lights having passed through the respective polarizing plates 24 pass through the corresponding microlenses 22.

Next, an operation of the solid imaging device 1 according to the embodiment will be described.

As shown in FIG. 2, the light from a subject 33 is once condensed by passing through the imaging lens 12, and then enters into the polarizing plate array substrate 13 disposed behind the imaging plane 28. The lights having entered into the polarizing plate array substrate 13 are respectively polarized by the polarizing plate 24a, the polarizing plate 24b, the polarizing plate 24c and the polarizing plate 24d, to thereby enter into the respective microlenses 22 corresponding to the respective polarizing plates. Then, the lights having entered into the respective microlenses 22 are condensed for each microlens 22 by passing through the corresponding microlenses 22, and an image is formed for each microlens 22 on the upper side 21 of the imaging substrate 15. The image formed for each microlens 22 is defined to be a microlens image 34.

As shown in FIG. 4A, a microlens image 34a, a microlens image 34b, a microlens image 34c, and a microlens image 34d, formed by imaging the light polarized by the polarizing plate 24a, the polarizing plate 24b, the polarizing plate 24c, and the polarizing plate 24d having polarization axes at 0 degree, 45 degrees, 90 degrees and 135 degrees, respectively, through the use of the microlenses 22 corresponding to each of the polarizing plate 24, are arranged in a matrix form on the upper side 21 of the imaging substrate 15. The image of a subject “A” is formed by condensing light by the plurality of microlenses 22. This image is converted into an electric signal by the imaging circuit 16, and then output to the ISP 11. In the ISP 11, this electrical signal is stored in the image capturing section 18 via the camera module interface 17. Then, among the images formed by the respective microlenses 22, the signal processing section 19 enlarges and synthesizes the microlens images 34 having the same polarization axis direction, thereby obtaining a two-dimensional image by a specific polarization axis. This two-dimensional image is output to an external section via the driver interface 20 as necessary. As shown in FIG. 4B when tacking out the microlens images 34a having the polarization axis of 0 degree, the respective microlens images 34a have portions captured in an overlapping manner of the subject “A”. Then, an image is synthesized so that the overlapped portions of the respective microlens images 34a are superimposed.

In this manner, as shown in FIG. 4C, a two-dimensional image resulting from synthesizing the plurality of microlens images 34a having the polarization axis at 0 degree is obtained. Furthermore, two-dimensional images of the respective microlens images 34 having the polarization axes at 45 degrees, the polarization axis at 90 degrees, and the polarization axis at 135 degree are constituted.

Next, the effects of the embodiment will be described. According to the embodiment, a two-dimensional image resulting from being synthesized for each polarization axis of the polarizing plate can be obtained. By using such an image, it is possible to remove light having dependency on the polarization axis such as reflected light from a window glass, for example. Thus, it is possible to enhance the visibility particularly in a burglar camera.

Furthermore, when the polarization major axis is visualized into a two-dimensional image, for example, by a color contour or the like, it is possible to make convex and concave portions on the surface of the subject stand out regardless of the color of the subject. Therefore, in a product test, it is possible to provide an image whose scratches on the surface if any are less likely to be overlooked.

Furthermore, because of not making use of the system of mechanically rotating the polarizing plates, but making use of the polarizing plate array substrate in which plural kinds of polarizing plates having mutually different polarization axes are arranged in a matrix form, a mechanism for rotating the polarization plates is not required. As a result, it is possible to realize a reduction in size of the solid imaging device. Since movable portions are also few, it is possible to prevent a breakdown due to metal fatigue.

In the embodiment, the polarizing plate array substrate 13 is disposed on the microlens array substrate 14. However, the polarizing plate array substrate 13 may be disposed under the microlens array substrate 14. Moreover, the polarization axes of the polarizing plates in the polarizing plate array substrate 13 are not limited to axes in the four directions at 0 degree, 45 degrees, 90 degrees, and 135 degrees. Furthermore, it is not always necessary that the polarizing plate array substrate 13 and the microlens array substrate 14 are formed on the same substrate, and each of the substrates may be separated.

### Second Embodiment

Next, a second embodiment will be described. The embodiment relates to a method of obtaining a polarization major axis from an image captured by the solid imaging device 1 and also relates to a method of obtaining a two-dimensional image by the polarization major axis.

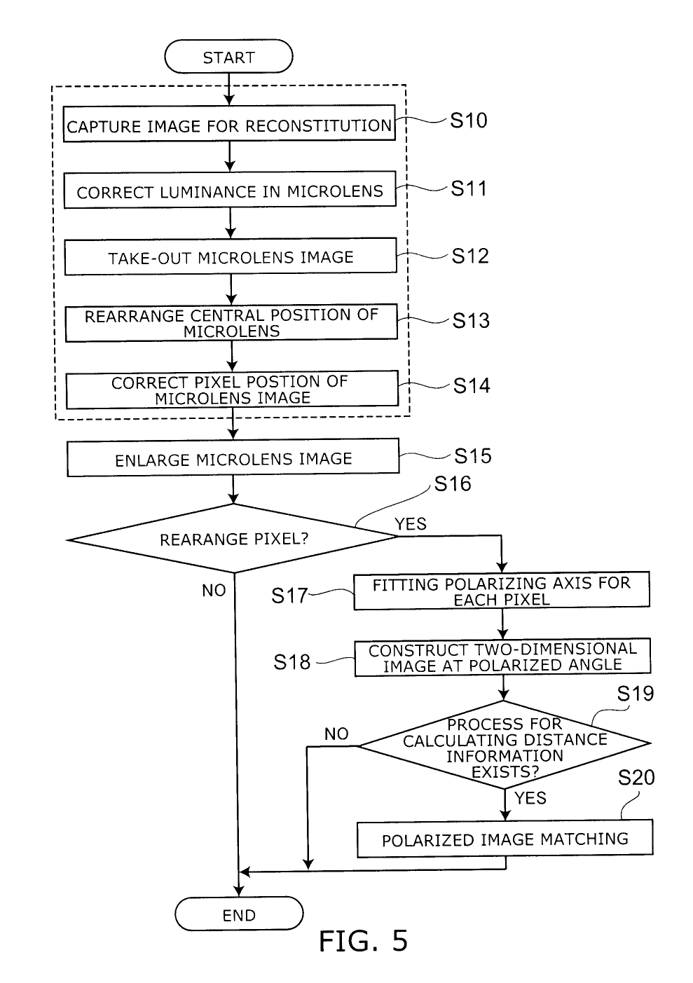

FIG. 5 is a flowchart diagram illustrating a method of obtaining a polarization major axis from an image captured in the second embodiment.

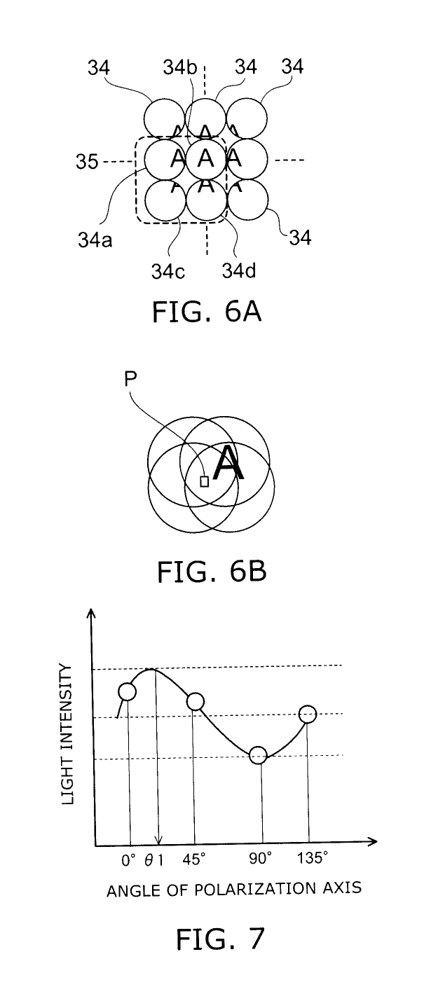

FIG. 6A is a diagram illustrating an image formed for each microlens in the second embodiment.

FIG. 6B is a diagram illustrating a two-dimensional image obtained by image processing of the image of FIG. 6A.

FIG. 7 is a chart diagram illustrating a relationship between the polarization axis of the polarization plate and the light intensity of the subject in the second embodiment, in which the horizontal axis indicates an angle of the polarization axis, and the vertical axis indicates the light intensity.

The configuration of the embodiment is the same as the configuration of the above described first embodiment.

Next, the operation of the embodiment will be described.

As shown in step S10 of FIG. 5, first, an image for reconstituting to obtain the polarization major axis is captured. Next, as shown in step S11, the luminance of the microlens image 34 is corrected.

Then, as shown in FIG. 6A and step S12 of FIG. 5, the microlens image 34 in the prescribed range is taken out.

Therefore, as shown in step S13 of FIGS. 5 and 6B, central positions of the microlens images 34 are rearranged. That is, an error in mounting the microlens array substrate 14 and the imaging substrate 15, and an image distortion due to the imaging lens 12 are corrected. Next, as shown in step S14, The pixel positions of the microlens image 34 on the upper side 21 of the imaging substrate 15 of the microlens image 34 are corrected. Then, as shown in step S15, the process of enlarging the microlens image 34 is performed. Thereafter, as show in step S16, it is determined if there is any overlapping between the microlens images 34 for each pixel. If there is no overlapping between the microlens images 34, the process is terminated as shown in step S16.

If there is any overlapping between the microlens images 34, as shown in step S17, the fitting of the polarization axis for each pixel is performed. In the pixels P within the area, in which the four images 34 of the microlens image 34a, the microlens image 34b, the microlens image 34c, and the microlens image 34d are overlapped, images of the same points in the subject are formed by the plurality of microlenses 22. That is, when the light having passed through the imaging lens 12 enters into the plurality of the microlenses 22 of the microlens array substrate 14, and images are formed on the upper side 21 of the imaging substrate 15 for the respective microlenses 22, the parallax is caused between the respective microlenses 22 due to a difference in position of the respective microlenses 14. However, since a difference in parallax is small, the image of the subject 33, while being slightly displaced, appears in the plurality of microlens images 34.

As shown in FIG. 7, the respective polarization axes of the microlens images 34 overlapped onto the pixel P. are in the direction 29 at 0 degree, the direction 30 at 45 degrees, the direction 31 at 90 degrees, and the direction 32 at 135 degrees. Thus, the polarization curve is obtained by plotting the relationship between the angle θ of the polarization axis of the polarizing plate 24 and the light intensity I in this state, and performing the fitting on this plotting. For the fitting, the sine function of I=α+β sin (2θ+γ) is used. Here, the relationship between the angles θ of the three polarization axes and the light intensities in the corresponding states is substituted into the sine function. As a result, a value α, a value β, and a value γ can be obtained.

Thereafter, using the resulting sine function, the polarization axis angle θ1 at which the light intensity is maximized, i.e., the polarization major axis θ1 is obtained. In this manner, it is possible to obtain the polarization major axis from the image captured by the solid imaging device 1.

Subsequently, the respective polarization major axes are obtained from all the pixels in which the microlens images 34 are overlapped. Then, as shown in step S18, the polarization major axes thus obtained are displayed, for example, by the color contour. As a result, a two-dimensional image by the polarization major axis can be obtained.

Then, as shown in step S19, the sequence is terminated when there is no process for computing the distance between the subject 33 and the solid imaging device 1. In contrast, if there is a process for calculating the distance between the subject 33 and the solid imaging device 1, the sequence proceeds to step S20. The step S20 will be described later.

Next, the effects of the embodiment will be described.

According to the embodiment, a two-dimensional image of the polarization major axis can be obtained. Such image also makes if possible to make the convex and concave portions on the surface of the subject stand out regardless of the color of the subject. Therefore, in the product test, it is possible to provide an image whose scratches on the surface if any are less likely to be overlooked.

Other than the above effects, the embodiment exhibits the same effects as those of the above described first embodiment.

### Modified Example of Second Embodiment

Next, a modified example of the second embodiment will be described.

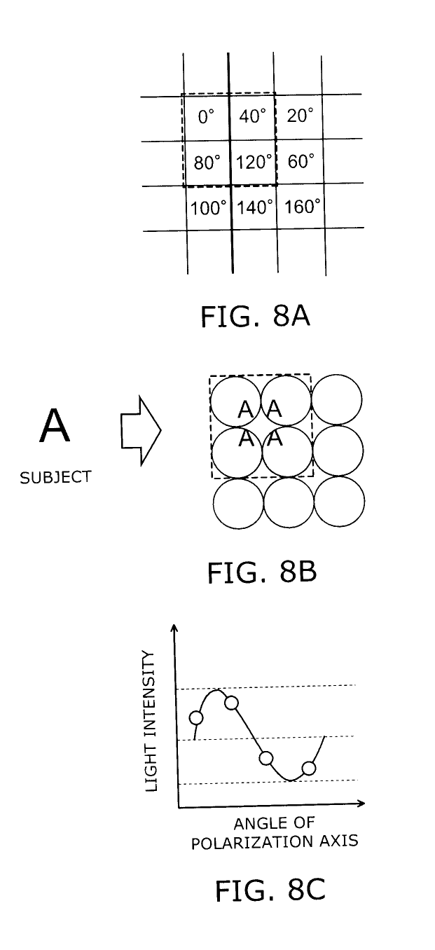

FIG. 8A is a diagram illustrating a polarizing plate array substrate in a modified example of the second embodiment.

FIG. 8B is a diagram illustrating an image formed for each microlens.

FIG. 8C is a chart diagram illustrating a relationship between the polarization axis of the polarization plate and the light intensity of the subject, in which the horizontal axis indicates an angle of the polarization axis, and the vertical axis indicates the light intensity.

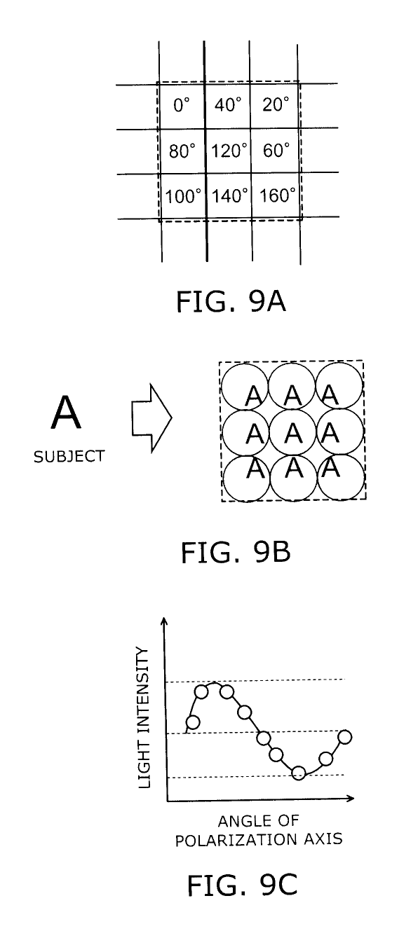

FIG. 9A is a diagram illustrating a polarizing plate array substrate in the modified example of the second embodiment.

FIG. 9B is a diagram illustrating an image formed for each microlens.

FIG. 9C is a chart diagram illustrating a relationship between the polarization axis of the polarization plate and the light intensity of the subject, in which the horizontal axis indicates an angle of the polarization axis, and the vertical axis indicates the light intensity.

As shown in FIG. 8A, in the modified example, other than the polarizing plate 24 having the polarization axis in the direction 29 at 0 degree, polarizing plates 24 having polarization axes in directions at 20 degrees, 40 degrees, 60 degrees, 80 degrees, 100 degrees, 120 degrees, 140 degrees and 160 degrees are provided.

Then, as shown in FIG. 8B, an image of the subject “A” is formed by the respective microlenses 22 corresponding to the polarizing plates 24 having polarization axes in directions at 0 degree, 40 degrees, 80 degrees, and 120 degrees.

Thereafter, in the same manner as the above described second embodiment, a polarization major axis can be obtained by fitting into the sine function.

Next, as shown in FIGS. 9A to 9C, by changing at least either one of the distance between the imaging lens 12 and the microlens array substrate 15, and the distance between the microlens array substrate 14 and the imaging substrate 15 depending on a movable section 36 (see FIG. 2), the imaging magnification of the microlens image 34 is increased. As a result, an image of the subject “A” is formed not only by the respective microlenses 22 corresponding to the polarizing plates 24 having polarization axes in directions at 0 degree, 40 degrees, 80 degrees, and 120 degrees but also by the respective microlenses 22 corresponding to the polarizing plates 24 having polarization axes in directions at 20 degrees, 60 degrees, 100 degrees, 140 degrees and 160 degrees.

Thereafter, the polarization major axis is obtained by fitting into the sine function like in the case of the above described second embodiment.

Next, the effects of the modified example will be described.

According to the modified example, it is possible to be adjusted such that the subject 33 appears in many microlens arrays 22. Therefore, fitting can be performed using many data, which in turn makes it possible to determine the polarization major axis with a higher degree of accuracy. As a result, a quality of the two-dimensional image can be improved by the polarization major axis.

### Third Embodiment

Next, a third embodiment will be described. The embodiment relates to a method of obtaining a distance between the subject 33 and the solid imaging device 1.

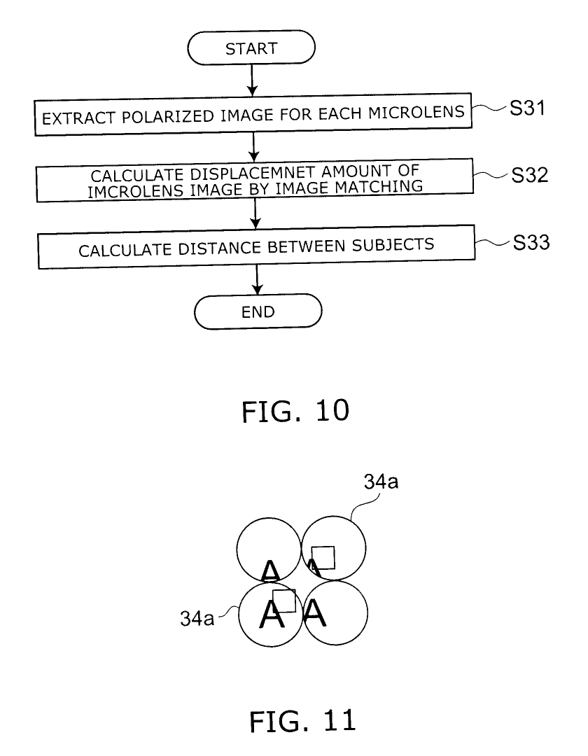

FIG. 10 is a flowchart diagram illustrating a method of matching images in the third embodiment.

FIG. 11 is a diagram illustrating an image formed for each microlens in the third embodiment.

As shown in the above described FIG. 2, the distance between the imaging lens 12 and the subject 33 is defined to be a distance A, the distance between the imaging lens 12 and an imaging plane 27 is defined to be a distance B, the distance between the imaging plane 27 of the imaging lens 12 and the microlens array substrate 14 is defined to be a distance C, the distance between the microlens array substrate 14 and the imaging substrate 15 is defined to be a distance D, and the distance between the imaging lens 12 and the microlens array substrate 14 is defined to be a distance E. Furthermore, a focal distance of the imaging lens 12 is defined to be a distance f, and a focal distance of the microlens 22 is defined to be a distance g.

From the formula of the lens shown in the numerical formula (1) described below, a value for the distance B changes with a change in the distance A between the imaging lens 12 and the subject 33.

$$\begin{matrix}[ Numerical Formula 1 ] & \\ \frac{1}{A} + \frac{1}{B} = \frac{1}{f} & ( 1 )\end{matrix}$$

As shown in FIG. 2, from the positional relationship of the optical system, since the relationship of: Distance B+Distance C=Distance E holds, a value for the distance C changes with the distance B. From the formula of the lens indicated by the following numerical formula (2) described below for the microlens 22, a value for the distance D changes with the distance C.

$$\begin{matrix}[ Numerical Formula 2 ] & \\ \frac{1}{C} + \frac{1}{D} = \frac{1}{g} & ( 2 )\end{matrix}$$

As a result, an image formed by passing through the respective microlenses 22 becomes an image obtained by reducing the imaging plane 27 that is a virtual image of the imaging lens 12 at a reduction ratio of M. Here, the reduction ratio M is the distance D/the distance C, which can be expressed by the numerical formula (3) described below.

$$\begin{matrix}[ Numerical Formula 3 ] & \\ \frac{D}{C} = \frac{D}{E - B} = \frac{D}{E - \frac{Af}{A - f}} = \frac{D ( A - f )}{E ( A - f ) - Af} = M & ( 3 )\end{matrix}$$

In the same way, when the distance A between the imaging lens 12 and the subject 33 changes, respective values for the distance B, the distance C and the distance D change accordingly. Therefore, the reduction ratio M of the image of the microlens 22 also changes.

By rearranging the above numerical formula (3) with respect to the distance A, the following numerical formula (4) can be obtained.

$$\begin{matrix}[ Numerical Formula 4 ] & \\ A = \frac{( D - ME ) f}{D - ME + Mf} & ( 4 )\end{matrix}$$

20

Therefore, since respective values for the distance D, the distance E, and the distance f are known, by calculating the reduction ratio M of the image by the microlens 22, it is possible to derive a value of the distance A from the above numerical formula (4).

From the geometric relationship of light, when an amount of displacement of images between the microlenses 22 is set to and a distance between centers of the microlenses 22 is set to L, the reduction ratio M can be expressed by the following numerical formula (5):

$$\begin{matrix}[ Numerical Formula 5 ] & \\ M = \frac{Δ}{L} & ( 5 )\end{matrix}$$

Therefore, the reduction ratio M can be obtained by obtaining an amount of displacement between the microlenses 22 by the image matching. As a result, a distance between the subject 33 and the solid imaging device 1 can be obtained.

Next, a method of matching images will be described. As shown in step S19 in the above described FIG. 5, if there is a process for calculating the distance between the subject 33 and the solid imaging device 1, the matching of the polarized images is performed as shown in step S20.

As shown in step S31 of FIG. 10, in order to prevent mismatching caused by comparing images having different polarization axes, in the image matching between the microlenses 22, the microlens images 34 having the same polarization axis are compared with one another.

Next, as shown in step S32, the displacement in the microlens images 34 is calculated by the image matching.

As shown in FIG. 11, an amount of displacement between the microlens images 34a respectively having the polarization axis at 0 degree is measured. For such polarized images having the same polarization axis, it is possible to obtain a matching position by using an image matching evaluation value such as SAD or SSD. As a result, a displacement amount of the images between the microlenses 22 can be obtained.

Then, as shown in step S33 in FIG. 10, by substituting the value obtained from the above numerical formula (5) into the numerical formula (4), the distance between the subject 33 and the solid imaging device 1 can be obtained.

Next, the effects of the embodiment will be described.

According to the embodiment, since the microlens images 34 having the same polarization axis are used for the image matching, it is possible to compute distance information by using an image matching method generally used. Moreover, by constructing a two-dimensional image by the polarization major axis plot for each microlens image through the use of an overlapped portion between the microlens images as described above, and by applying the image matching, it is possible to obtain a displacement amount by using the polarized light information. In this case, it is possible to perform the image matching also in the case where the subject and the background are in the same color, which is difficult to perform the image matching with the visible light image, or to perform the image matching on scratches formed on the subject, thereby improving a distance precision. Furthermore, since the distance can be measured by the single imaging lens 12 and the single imaging element 15, a reduction in size of the device can be realized as compared with the case of using a plurality of imaging lenses 12 and a plurality of imaging elements 15.

### Modified Example of Second and Third Embodiments

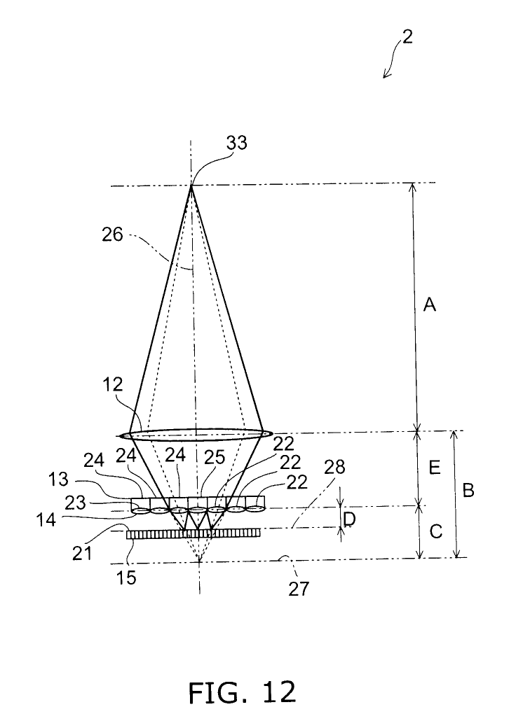

FIG. 12 is an optical model diagram illustrating a solid imaging device 2 according to a modified example of the second and third embodiments.

As shown in FIG. 12, in the solid imaging device 2 according to the modified example, the imaging plane 27 of the imaging lens 12 is disposed behind the imaging substrate 15. That is, the relationship of: Distance E+Distance C=Distance B holds. In this case, the formula of the lens related to the microlens can be expressed by the following numerical formula (6).

$$\begin{matrix}[ Numerical Formula 6 ] & \\ - \frac{1}{C} + \frac{1}{D} = \frac{1}{g} & ( 6 )\end{matrix}$$

Therefore, in this case, the relationship between the distance A and the reduction ratio M can be expressed by the following numerical formula (7).

$$\begin{matrix}[ Numerical Formula 7 ] & \\ A = \frac{( D + ME ) f}{D + ME - Mf} & ( 7 )\end{matrix}$$

Other than the above, the configuration and the operation of the modified embodiment are the same as those of the above described third embodiment.

Next, the effects of the modified example will be explained.

According to the modified example, an imaging plane 27 can be approximated to the imaging plane 28 in a vicinity of the imaging lens 12. As a result, it is possible to reduce the size of the solid imaging device 2. Other than the above, the effects of the modified example are the same as those of the second and third embodiments.

According to the above described embodiment, it is possible to provide the solid imaging device which realizes polarimetry with a high degree of accuracy.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A solid imaging device, comprising:
an imaging substrate having a plurality of pixels formed on an upper side thereof;
an imaging lens which is provided above the imaging substrate, and in which an optical axis intersects with the upper side of the imaging substrate;
a microlens array substrate which is provided between the imaging substrate and the imaging lens, and in which a surface having a plurality of microlenses arranged two-dimensionally intersects with the optical axis; and
a polarizing plate array substrate which is provided between the imaging substrate and the imaging lens, and in which a plurality of kinds of polarizing plates having polarization axes in mutually different directions are arranged two dimensionally,
a light polarized by one of the polarizing plates being condensed by one of the microlenses to form an image on the upper side of the imaging substrate.

2. The device according to claim 1, wherein the polarization axes are in directions inclined by 0 degree, 45 degrees, 90 degrees and 135 degrees from one direction in a plane of the polarizing plate array substrate.

3. The device according to claim 1, wherein the polarizing plate array substrate is disposed on the microlens array substrate.

4. The device according to claim 1, wherein among a plurality of images formed by the microlenses, a two-dimensional image is obtained by synthesizing a plurality of images formed by light polarized by the plurality of polarizing plates having the polarization axes mutually in the same direction.

5. The device according to claim 4, wherein the two-dimensional image is obtained for each polarization axis.

6. The device according to claim 1, wherein among plurality of images formed by the microlenses, a plurality of images formed by light polarized by the plurality of polarizing plates having mutually different polarizing axes are superimposed, and a polarization major axis is obtained based on a light intensity of the pixels in which the image is formed.

7. The device according to claim 6, wherein by fitting a plot representing a relationship between an angle of the polarization axis and the light intensity into a sine function, the angle at which the light intensity has a maximum value is set to the direction of the polarization major axis.

8. The device according to claim 6, wherein the polarization major axis of the plurality of pixels over the area in which the image is formed, the polarization major axis is obtained for each of the plurality of pixels, and a two-dimensional image by the polarization major axis is obtained.

9. The device according to claim 8, wherein the two-dimensional image is displayed by a color contour.

10. The device according to claim 6, further comprising:
a movable section for changing at least any of a distance between the imaging lens and the microlens array substrate and a distance between the microlens array substrate and the imaging substrate.

11. The device according to claim 10, wherein mutually different directions of the polarization axes are increased by changing any of the distances.

12. The device according to claim 11, wherein directions of the polarization axes before changing any of the distances are set to directions respectively inclined by 0 degree, 40 degrees, 80 degrees and 120 degrees from one direction within the face of the polarizing plate array substrate, and directions of the polarization axes after changing any of the distances are set to directions respectively inclined by 0 degree, 20 degrees, 40 degrees, 60 degrees, 80 degrees, 100 degrees, 120 degrees, 140 degrees and 160 degrees from the one direction.

13. The device according to claim 1, wherein a distance between a subject and the imaging lens is obtained based on a displacement in positions of images formed by two of the microlenses, and a distance between the two microlenses.

14. The device according to claim 13, wherein the images formed by the two microlenses are images formed by light polarized by the polarizing plates in which directions of the polarization axes are mutually equal.

15. The device according to claim 1, wherein an imaging plane of the imaging lens is above the polarizing plate array substrate.

16. The device according to claim 15, wherein with respect to an image on the imaging plane of the imaging lens, when a reduction ratio indicative of a ratio of reducing an image formed by passing through each of the microlenses is set to M, a distance between the two microlenses is set to L, and a displacement in position of the images formed by the two microlenses is set to Δ, M is obtained by Δ/L.

17. The device according to claim 16, wherein when a distance between the imaging lens and the subject is set to A, a distance between the microlens array substrate and the imaging substrate is set to D, a distance between the imaging lens and the microlens array substrate is set to E, and a focal distance of the imaging lens is set to f, A is obtained by the following formula:
$$A = \frac{( D - ME ) f}{D - ME + Mf} .$$

18. The device according to claim 1, wherein an imaging plane of the imaging lens is below the imaging substrate.

19. The device according to claim 18, wherein with respect to an image on the imaging plane of the imaging lens, when a reduction ratio indicative of a ratio of reducing an image formed by passing through each of the microlenses is set to M, a distance between the two microlenses is set to L, and a displacement in position of the images formed by the two microlenses is set to Δ, M is obtained by Δ/L.

20. The device according to claim 19, wherein when a distance between the imaging lens and the subject is set to A, a distance between the microlens array substrate and the imaging substrate is set to D, a distance between the imaging lens and the microlens array substrate is set to E, and a focal distance of the imaging lens is set to f, A is obtained by the following formula:
$$A = \frac{( D - ME ) f}{D - ME + Mf} .$$
